(19) United States
(12) Patent Application Publication
(10) Pub. No.: US 2026/0040981 A1
(43) Pub. Date: Feb. 5, 2026

(54) INTEGRATED CIRCUIT AND PACKAGE WITH IMPROVED FAULT PROTECTION

(71) Applicant: Monolithic Power Systems, Inc., Kirkland, WA (US)

(72) Inventors: Zheng Luo, San Jose, CA (US); Yiming Li, Shanghai (CN); Hunt Hang Jiang, Saratoga, CA (US)

(21) Appl. No.: 18/791,387

(22) Filed: Jul. 31, 2024

(51) Int. Cl. H01L 23/498; H01L 23/00; H01L 23/522; H01L 23/62; H01L 27/02

(52) U.S. Cl. CPC H01L 23/49844; H01L 23/5223; H01L 23/62; H01L 24/48; H10D 89/60; H01L 24/32; H01L 24/73; H01L 2224/32225; H01L 2224/48225; H01L 2224/73265; H01L 2924/1815

(57) ABSTRACT

An integrated circuit (“IC”) chip having fault protection features. The IC chip in an embodiment may include a lead frame having a first portion adapted to accommodate an IC bare die and a second portion separated from first portion and adapted to be coupled to the IC bare die by an electrically conductive connector. The electrically conductive connector includes a connector bridging portion having a reduced size in comparison with a remainder of the electrically conductive connector and having an elevated portion that is protruding relative to the remainder of the electrically conductive connector.

### TECHNICAL FIELD

This disclosure relates generally to semiconductor devices, and more particularly but not exclusively relates to integrated circuit and package with fault protection.

### BACKGROUND

Integrated circuits (“ICs”) are widely used in various electronic and/or electric applications. While demands on the ICs' power handling capability is increasing, it is meanwhile more and more desirable for ICs being cost effective, size saving and robust and safe for operation. For instance, an IC with fault protection mechanism may be helpful to improve operation safety or fail safety of a system with the IC integrated in. To provide an example, a fault condition in the IC may include a short circuit event or an overcurrent event that can generally lead to damage to the IC itself and/or to other components in the system.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a block diagram of a system 100 including an integrated circuit (“IC”) with fault protection in accordance with an embodiment of the present invention.

FIG. 2 illustrates a block diagram of an IC chip 110 with fault protection in accordance with an embodiment of the present invention.

FIG. 3A illustratively shows a top plan view of the IC chip 110 in a package 30 in accordance with an embodiment of the present invention.

FIG. 3B illustratively shows a cross sectional view of the IC chip 110 taken along the sectional line A-A′ in top plan view of FIG. 3A in accordance with an embodiment of the present invention.

FIG. 3C exemplarily illustrates a top plan view of the IC chip 110 in accordance with an alternative embodiment of the present invention.

FIG. 3D exemplarily illustrates a cross-sectional view of the IC chip 110 taken along the sectional line A-A′ in top plan view of FIG. 3A or FIG. 3C in accordance with an alternative embodiment of the present invention.

FIG. 4 illustratively shows a cross-sectional view of the IC chip 110 illustrating how a risk of causing flame or forming a secondary conductive path can be eliminated or reduced in an example embodiment.

FIG. 5A illustratively shows a top plan view of the IC chip 110 in a package 30 in accordance with still an alternative embodiment of the present invention.

FIG. 5B illustratively shows a top plan view of the IC chip 110 in a package 30 in accordance with yet another alternative embodiment of the present invention.

FIG. 5C exemplarily illustrates a cross-sectional view of the IC chip 110 taken along the sectional line A-A′ in top plan view of FIG. 5B in accordance with yet another alternative embodiment of the present invention.

FIG. 6 shows a waveform diagram to exemplarily illustrate the working principles of the fuse-like current limit protection and the fuse-like protection mode of the IC 110 in accordance with an embodiment of the present invention.

### SUMMARY

There has been provided, in accordance with an embodiment of the present disclosure, an integrated circuit (“IC”) chip including a lead frame, an IC bare die and an electrically conductive connector. The lead frame may include a first portion and a second portion separated from each other. In an embodiment, the IC bare die may be mounted on the first portion of the lead frame with a die bottom surface of the IC bare die attached to the first portion and a die top surface of the IC bare die having a first contact pad formed, the die top surface being opposite to the die bottom surface. In an embodiment, the electrically conductive connector may be coupled between the first contact pad of the IC bare die and the second portion of the lead frame. The electrically conductive connector may include a connector bridging portion having a reduced size in comparison with a remainder of the electrically conductive connector. In an embodiment, the connector bridging portion may have an elevated portion being vertically higher than the remainder of the electrically conductive connector with reference to a bottom surface of the IC chip.

There has also been provided, in accordance with an embodiment of the present disclosure, an electrically conductive connector adapted to be used in a package for an IC. In an embodiment, the electrically conductive connector may include a connector bridging portion having a reduced size in comparison with a remainder of the electrically conductive connector. The connector bridging portion may have an elevated portion that is protruding relative to the remainder of the electrically conductive connector.

There has also been provided, in accordance with an embodiment of the present disclosure, an IC chip having an input pin and an output pin. The IC chip may further include a power switch coupled between the input pin and the output pin, a current sense pin adapted to be configured to provide a current sense signal indicative of a current flowing between the input pin and the output pin, and a fuse-like protection pin adapted to be configured to support a fuse-like protection mode when a capacitive element is coupled to the fuse-like protection pin. In an embodiment, the current sense signal may be clamped at a predetermined clamp voltage threshold once the current sense signal reaches the predetermined clamp voltage threshold. In an embodiment, the IC chip may be configured to enter into the fuse-like protection mode once a fuse-like protection threshold is triggered. In an embodiment, the IC chip may include a package level fuse protection structure integrated and coupled in series with the output pin.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled,” as used herein, is defined as directly or indirectly connected in an electrical or non-electrical manner. When an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. In addition, “electrically connected” or “electrically coupled” means the concept including a physical connection and a physical disconnection, which enables an electrical coupling between elements. It can be understood that when an element is referred to with “first” or “second” or the like, the element is not limited thereby. The terms “first” or “second” or the like may be used only for a purpose of distinguishing the element from the other elements being modified by these terms and may not limit the sequence or importance of the elements being modified unless the context clearly dictates otherwise. The terms “a,” “an,” and “the” include plural reference, and the term “in” includes “in” and “on” unless the context clearly dictates otherwise. The phrase “in one embodiment,” as used herein does not necessarily refer to the same embodiment, although it may. The term “or” is an inclusive “or” operator, and is equivalent to the term “and/or” herein, unless the context clearly dictates otherwise. The term “and/or” may include individual or any combination of the elements being referenced in conjunction with the term. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signals. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

The terms “left,” right,” “in,” “out,” “front,” “back,” “up,” “down, “top,” “atop”, “bottom,” “over,” “under,” “above,” “below”, “lower”, “upper” and the like in the description and the claims, if any, are used for descriptive purposes and for convenience of explanation and not necessarily for describing permanent relative positions. It is to be understood that the terms so used are interchangeable under appropriate circumstances such that embodiments of the invention described herein are, for example, capable of operation in other orientations than those illustrated or otherwise described herein, and the claims are not particularly limited by the positions or directions as described with those terms.

For convenience of explanation, the present disclosure may take a specific semiconductor device as an example for the explanation, but this is not intended to be limiting and persons of skill in the art will understand that the structure and principles taught herein also apply to other semiconductor devices.

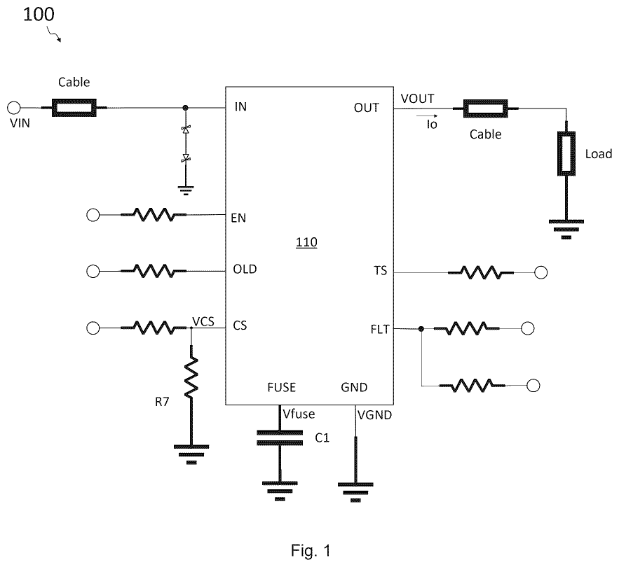

FIG. 1 illustrates a block diagram of a system 100 including an integrated circuit (“IC”) with fault protection in accordance with an embodiment of the present invention. In the example of FIG. 1, the system 100 may include an IC 110, a power source 120, and a load device 130.

The IC 110 may be adapted to be used for sourcing power from the power source 120 to the load device 130. The power source 120 may comprise a power supply such as a battery/battery pack or other circuit for providing power to another circuit. In the example of FIG. 1, the power source 120 provides power in the form of an input voltage VIN, which may be a DC voltage.

In an example, the system 100 may further include a controller such as a single-chip microcontroller to co-work with the IC 110. In an example, the IC 110 may be a monolithic IC switch device. The IC 110 may be a “smart switch” device in that it may be controllable by a microcontroller and may have integrated driving circuits for driving a power transistor and may further include integrated monitoring circuits and/or integrated protection circuits and/or diagnostic circuits. With the monitoring or the diagnostic circuits, the IC 110 may provide switch and power supply conditions to the microcontroller for instance. With the monitoring and/or the diagnostic circuits and/or the protection circuits, the IC 110 may detect fault events such as over current and/or short circuit and/or over temperature and/or loss of power supply and/or loss of system ground etc. and protect the IC 110 itself and/or other components in the system from being damaged due to the fault events, for instance, or at least reduce the risk of the IC 110 and/or other components in the system being damaged.

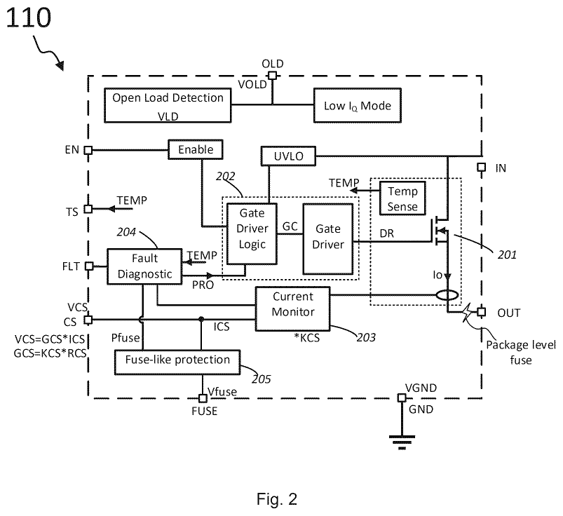

In one embodiment, the IC 110 is a monolithic IC in that it is a single-die chip. In the example of FIG. 1, the IC 110 has a plurality of pins that may include an input pin IN for receiving an input power supply voltage VIN and an output pin OUT that may be adapted to be connected to a load such as the load device 130. In an embodiment, the IC 110 may include a power switch (see FIG. 2, 201), such as a power field effect transistor (FET). The power switch may have and a first terminal (e.g., a source) connected to the output pin OUT and a second terminal (e.g., a drain) connected to the input pin IN. The IC 110 may further include circuitry that drives a third terminal that may generally be a control terminal (e.g., a gate) of the power switch for turning the power switch ON or OFF in a controlled manner. When turned ON, the power switch connects the input power supply that is connected to the IN pin to the load that is connected to the OUT pin. In the example of FIG. 1, the IC 110 may support operation with an input power supply voltage ranging from 3.2V to 36V and provide a load current up to 40 A to the load device 130 for illustration purposes. As can be appreciated, the system 100 can also be employed to connect other input power supplies with different voltage and current ratings to a load.

The load device 130 may include but not limited to capacitive loads such as electronic control unit, resistive load (e.g., heaters), and/or inductive load (e.g., solenoids, motors, valves)

In an embodiment, as shown in the example of FIG. 1, the IC 110 may further include an enable pin EN adapted to be configured to receive an enable signal for instance from a microcontroller or other element in the system 100. The enable pin EN (may also referred to as EN pin for simplicity) may be used for enabling/disabling the IC 110. For instance, the EN pin may be pulled down to let a voltage at the EN pin to reach or to be lower than a disable threshold to disable the IC 110 from operation, that is, to shut down the IC 110. The EN pin may be pulled up to let the voltage at the EN pin to reach or to be higher than an enable threshold to enable the IC 110 for operation. The enable threshold may be higher than the disable threshold. For example, in an embodiment, the disable threshold may be set at 0.8V while the enable threshold may be set at 2.2V. As can be appreciated by those of ordinary skill in the art that the disable threshold and the enable threshold may be set to other voltage values according to practical application conditions and requirements.

In an embodiment, as shown in the example of FIG. 1, the IC 110 may further include a fault indication pin FLT for indicating a fault even (e.g., any one or more of the fault events including over current, over temperature, short circuit, power switch short, open load, etc.), and a ground pin GND for connecting the IC 110 to a system ground of the system 100 where the IC 110 is incorporated in. For instance, the IC 110 may be mounted on a circuit board with the system 100 configured thereon and the ground pin GND of the IC 110 may be connected to a ground plane or a ground pad/terminal of the system 100 on the circuit board.

In an embodiment, as shown in the example of FIG. 1, the IC 110 may further include a current sense (CS) pin for providing an indicator of an amount of an output current Io or the load current provided by the IC 110. In an embodiment, the CS pin may be adapted to provide a current sense signal VCS in the form of a voltage signal indicative of a current flowing between the IN pin and the OUT pin. In an embodiment, the IC 110 may be configured to provide the current sense signal VCS at the CS pin by applying a predetermined current sense gain GCS for instance in ohm (Ω) to the current Io flowing between the IN pin and the OUT pin. That is, VCS(V)=GCS(Ω)*Io(A). In an embodiment, the current sense signal VCS at the CS pin may be clamped at a predetermined clamp voltage threshold VCS_CL (for instance set to be 3V in an example) once the current sense signal VCS reaches the predetermined clamp voltage threshold VCS_CL. In other words, once the current sense signal VCS reaches the predetermined clamp voltage threshold VCS_CL, the current sense signal VCS will be kept at the threshold value VCS_CL and no longer increases with the current Io flowing between the IN pin and the OUT pin increasing.

In an embodiment, as shown in the example of FIG. 1, the IC 110 may further include a temperature sense (TS) pin for indicating a junction temperature (i.e., die temperature of the monolithic IC) of the IC 110. For various reasons including safety, trouble shooting, load balancing, etc., it is advantageous to know the junction temperature of the IC 110. Accordingly, in the example of FIG. 1, the IC 110 may be configured to provide a temperature sensing signal TEMP at the TS pin. The temperature sensing signal TEMP may be indicative of the junction temperature of the IC 110. The temperature sensing signal TEMP may be in an exemplary embodiment sent to a microcontroller for instance to report the die temperature information of the IC 110 so that customers using the IC 110 may be able to monitor the die temperature and execute other functions including but not limited to over temperature protection, trouble shooting, load balancing etc. accordingly. In one embodiment, the temperature sensing signal TEMP from the TS pin of the IC 110 may be a voltage that is proportional to the junction temperature (e.g., 10 mV/° C.). In one embodiment, the IC 110 may be configured to take into account the junction temperature in deciding whether to disable the IC 110, trigger an alarm, or report a fault event at the FLT pin, for example.

In an embodiment, as shown in the example of FIG. 1, the IC 110 may further include a fuse-like protection pin FUSE that may be adapted to be configured to support fuse-like current limit protection. In an embodiment, a capacitive element such as a capacitor C1 as exemplarily shown in FIG. 1 may be coupled between the fuse-like protection pin FUSE and the ground pin GND (or the system ground) to support the IC 110 being operated with fuse-like current limit protection. For instance, with the output current Io (or the load current) from the input pin IN to the output pin OUT increasing, as the current sense signal VCS would be clamped to the clamp voltage threshold VCS_CL (for instance set to be 3V in an example) once the current sense signal VCS reaches the predetermined clamp voltage threshold VCS_CL, an extra output current at the CS pin may flow to and be output from the fuse-like protection pin FUSE if the output current Io (or the load current) from the input pin IN to the output pin OUT keeps increasing after the current sense signal VCS reaches the clamp voltage threshold VCS_CL. In an embodiment, the IC 110 may enter into a fuse-like protection mode to provide fuse-like current limit protection when the current sense signal VCS reaches the clamp voltage threshold VCS_CL. In an embodiment, the clamp voltage threshold VCS_CL may be indicative of a fuse current limit threshold IFUSE_CL. In an embodiment, the IC 110 may enter into the fuse-like protection mode to provide fuse-like current limit protection when a fuse-like protection threshold is triggered, that is, when the current sense signal VCS reaches the clamp voltage threshold VCS_CL or when the output current Io (or the load current) from the input pin IN to the output pin OUT exceeds the fuse current limit threshold IFUSE_CL.

In an embodiment, the fuse current limit threshold IFUSE_CL may be determined following the equation (1) below, wherein Ibias may be a predetermined bias current with a bias current value chosen or set according to practical application requirements. For instance, in an example, the predetermined bias current Ibias may be set to have a bias current value of 6.5 A. One of ordinary skill in the art would understand that the specific exemplary values of each parameter or variable provided here throughout the disclosure are just to provide examples to help understand embodiments of the present invention and not intended to be limiting. For instance, the clamp voltage threshold VCS_CL may be set to other voltage values other than 3V, the predetermined bias current Ibias may be set to other current values other than 6.5 A. In an example, the predetermined bias current Ibias may be substantially 0 A.

IFUSE_CL(A)=VCS_CL(V)/GCS(Ω)+Ibias(A) (1)

In an embodiment, when the current sense signal VCS reaches the clamp voltage threshold VCS_CL or when the output current Io exceeds the fuse current limit threshold IFUSE_CL, a fuse current Ifuse which may be indicative of an amount of current value ΔIo that the output current Io has exceeded the fuse current limit threshold IFUSE_CL may charge the capacitor C1 coupled at the FUSE pin and a fuse voltage Vfuse at the FUSE pin may begin to increase. The amount of current value ΔIo may alternatively be referred to or considered as a current value difference between the output current Io and the fuse current limit threshold IFUSE_CL, and may be expressed as ΔIo=Io−IFUSE_CL. In an embodiment, the fuse current Ifuse may be proportional to a predetermined number J order of the current value difference ΔIo between the output current Io and the fuse current limit threshold IFUSE_CL. For example, the predetermined number J may be in a range from 2 to 4, and in an example, the predetermined number J is set to 3.2.

In the fuse-like protection mode, the IC 110 may not shut down immediately after triggering the fuse-like protection threshold, the IC 110 may be configured to shut down after a fuse-like protection period (or time interval) Tfuse. In an example, the fuse-like protection period Tfuse would change in opposite direction with the current Io flowing between the input pin IN and the output pin OUT, i.e., the higher the current Io goes, the shorter the fuse-like protection period Tfuse would be, and vice versa.

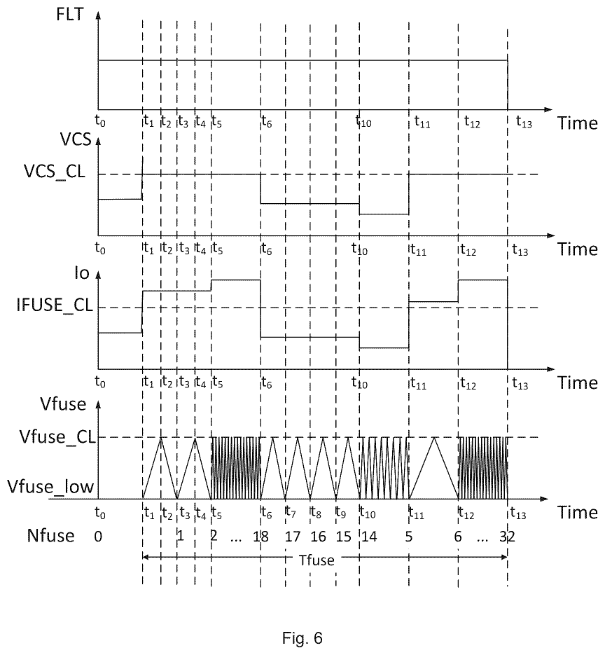

To provide an example, in an embodiment, the fuse-like protection period Tfuse may be determined based on charging and discharging the capacitive element C1 coupled to the FUSE pin. In an example, the fuse-like protection period Tfuse may be flexibly adjusted by adjusting a capacitance of the capacitive element C1. FIG. 6 shows a waveform diagram to exemplarily illustrate the working principles of the fuse-like current limit protection and the fuse-like protection mode of the IC 110 in accordance with an embodiment of the present invention. At time t1 for example, the output current Io (or the load current) exceeds the fuse current limit threshold IFUSE_CL and the IC 110 enters the fuse-like protection mode. In an embodiment, in the fuse-like protection mode, the IC 110 may be configured to start discharging the capacitive element C1 each time when the fuse voltage Vfuse at the FUSE pin reaches a fuse-like protection mode clamp voltage threshold Vfuse_CL (e.g., at time t2 in FIG. 6), and to stop discharging the capacitive element C1 and to make a fuse-like protection record each time when the fuse voltage Vfuse drops essentially to a discharge stop threshold Vfuse_low (e.g., at time t3 in FIG. 6) due to discharging of the capacitive element C1 at the FUSE pin. In an example, the fuse-like protection mode clamp voltage threshold Vfuse_CL may be set at 3V while the discharge stop threshold Vfuse_low may be set at substantially 0V.

One of ordinary skill in the art would understand that the fuse-like protection mode clamp voltage threshold Vfuse_CL and the discharge stop threshold Vfuse_low may be set to other threshold values according to practical application requirements. In an embodiment, the fuse-like protection record may be made for instance by an internal fuse counter in the IC chip 110 to let a record number Nfuse indicative of the times that the fuse-like protection record have been made to add 1. It may be understood by those of ordinary skill in the art that, the record number Nfuse actually is also indicative of the times that the fuse voltage Vfuse is charged to the fuse-like protection mode clamp voltage threshold Vfuse_CL and then subsequently discharged to the discharge stop threshold Vfuse_low. During the output current Io is above the fuse current limit threshold IFUSE_CL or during the current sense signal VCS is clamped at the predetermined clamp voltage threshold VCS_CL, each time once the fuse voltage Vfuse at the FUSE pin is discharged to be essentially at the discharge stop threshold Vfuse_low, the IC 110 stops discharging the fuse voltage Vfuse (i.e., stops discharging the capacitive elements C1 at the FUSE pin) while the fuse current Ifuse continues charging the capacitive element C1 until the fuse voltage Vfuse reaches the fuse-like protection mode clamp voltage threshold Vfuse_CL again and the IC 110 then starts to discharge the capacitive element C1 again and the process described above repeats until the record number Nfuse indicative of the times that the fuse-like protection record have been made reaches a predetermined number M, for instance M=32 in an example as shown in FIG. 6. When the record number Nfuse reaches the predetermined number M, the IC 110 may be configured to immediately shut down and pull the fault indication pin FLT to a logic low for instance. In this example, the fuse-like protection period Tfuse then actually refers to a period from the moment when the IC 110 enters the fuse-like protection mode to the moment when the record number Nfuse reaches the predetermined number M.

In an embodiment, if the output current Io decreases for instance below the fuse current limit threshold IFUSE_CL or the current sense signal VCS drops below the clamp voltage threshold VCS_CL (e.g., at time t6 in the example of FIG. 6) before the record number Nfuse reaches the predetermined number M, the IC 110 may further be configured to decrease the record number Nfuse by 1 each time when the fuse voltage Vfuse is charged to the fuse-like protection mode clamp voltage threshold Vfuse_CL and then discharged substantially to the discharge stop threshold Vfuse_low. As shown in the example of FIG. 6, from time t1 to t6, the output current Io is above the fuse current limit threshold IFUSE_CL and the record number Nfuse gradually increases to 18 at time t6 after the fuse voltage Vfuse has been charged to the fuse-like protection mode clamp voltage threshold Vfuse_CL and then discharged to the discharge stop threshold Vfuse_low for 18 times. From time t6 to t11, since the output current Io decreases below the fuse current current limit threshold IFUSE_CL and the current sense signal VCS drops below the clamp voltage threshold VCS_CL, the record number Nfuse gradually decreases from 18 to 5 at time t11 after the fuse voltage Vfuse has been charged to the fuse-like protection mode clamp voltage threshold Vfuse_CL and then discharged to the discharge stop threshold Vfuse_low for another 13. Then at time t11, the output current Io rises above the fuse current limit threshold IFUSE_CL again, and thus the record number Nfuse gradually increases again from 5 until at time t13 reaches the predetermined number M=32 in this example. At time t13, the IC 110 immediately shuts down and pulls the fault indication pin FLT to a logic low. The fuse-like protection period Tfuse then refers to the period from t1 to t13 in this particular example. In an embodiment where the bias current Ibias is not 0 A, the IC 110 may not decrease the record number Nfuse during 0 A<ΔIo<Ibias.

In an embodiment, as shown in the example of FIG. 1, the IC 110 may further include an open load detection pin OLD for supporting an open load detection function. To enable the open load detection function, a voltage VOLD at the open load detection pin OLD may be driven above a load detection threshold VLD (e.g., in an example the load detection threshold VLD may be set to 5V) when the EN pin is pulled low (i.e., the voltage at the EN pin reaches or goes lower than the disable threshold). The open load detection pin OLD may further support a mode control function. For instance, in an embodiment, the voltage VOLD at the open load detection pin OLD may be driven above the load detection threshold VLD (e.g., in an example VLD may be set to 5V) when the EN pin is pulled high (i.e., the voltage at the EN pin reaches or goes higher than the enable threshold) to let the IC 110 enter into a low quiescent current (Iq) mode. The open load detection pin OLD may be connected to the ground pin GND when none of the open load detection function and the mode control function is used. In an embodiment, as shown in the example of FIG. 1, the IC 110 may further support reverse battery protection. In practical application, a reverse battery connection event may cause a large current flowing from the OUT pin to the IN pin through a body diode of the power transistor (see e.g., in FIG. 2, 201) in the IC 110 which may result in which may result in undesirable large amount of heat, power loss and even IC damage. The IC 110 may detect whether there is a reverse battery connection event for instance by detecting whether the input voltage VIN at the IN pin goes negative (i.e., below 0V). In an example, the IC 110 may determine that the reverse battery connection event is detected when the input voltage VIN goes negative (i.e., VIN<0V). The IC 110 may immediately turn on the power transistor so that the OUT pin is electrically coupled to the IN pin once a reverse battery connection event is detected, and thereby pulling the output voltage VOUT at the OUT pin and the input voltage VIN at the IN pin to be substantially at the same voltage potential to prevent the large current flow from the OUT pin to the IN pin.

In an embodiment, as shown in the example of FIG. 1, the IC 110 may further support reverse load protection. In practical application, a reverse load event may cause a large current flowing from the OUT pin to the IN pin through the body diode of the power transistor (see e.g., in FIG. 2, 201) in the IC 110 if the power transistor is in OFF state, which may result in undesirable large amount of heat, power loss and even IC damage. In an example, the IC 110 may detect whether there is a reverse load event for instance by detecting whether the input voltage VIN at the IN pin goes lower than the output voltage VOUT at the OUT pin for a predetermined voltage difference value AV (e.g., 300 mV), i.e., VOUT−VIN>ΔV. The IC 110 may determine that the reverse load event is detected when the input voltage VIN is lower than the output voltage VOUT for at least the predetermined voltage difference value ΔV, that is, a voltage difference between the output voltage VOUT and the input voltage VIN exceeds the predetermined voltage difference value ΔV, i.e., VOUT−VIN>ΔV. In order to reduce power loss and heat and/or to prevent the IC 110 from being damaged, the IC 110 may immediately turn on the power transistor once the reverse load event is detected. In an embodiment, the IC 110 may continuously monitor a current flowing from the IN pin to the OUT pin after the power transistor is turned ON until the current exceeds a current threshold Ith (e.g., 200 mA) and the IC 110 will turn off the power switch again.

In an embodiment, as shown in the example of FIG. 1, the IC 110 may further support loss of ground protection. During a loss of ground event, a ground voltage VGND at the ground pin GND may increase and exceed a ground loss protection voltage threshold VGP. The IC 110 may be configured to monitor the ground voltage VGND at the ground pin GND and determine that a loss of ground event is detected when the ground voltage VGND exceeds the ground loss protection voltage threshold VGP. The IC 110 may turn off the power transistor (see e.g., in FIG. 2, 201) or keep the power transistor off when the loss of ground event is detected. In an embodiment, to protect any device that is interfacing with the IC 110, a current limiting resistive element may be coupled between pins of the IC 110 and the device interfacing with the IC 110.

In an embodiment, as shown in the example of FIG. 1, the IC 110 may further support loss of power supply protection. The IC 110 may be shut down regardless of the enable signal at the EN pin when a loss of power supply event occurs.

FIG. 2 illustrates a block diagram of an IC chip 110 with fault protection in accordance with an embodiment of the present invention. In the example of FIG. 2, the power switch 201 of the IC 110 is illustratively shown as to include a power field effect transistor (FET). A control module 202 may be configured to drive the control terminal of the power switch 201 to control the power switch 201 to perform ON and OFF switching in a controlled manner. For instance, in an exemplary embodiment, the control module 202 may include a gate driver logic circuit that may be adapted to receive a plurality of signals including the enable signal received at the EN pin to generate a control signal GC and a gate driver coupled to the gate driver logic circuit to receive the control signal GC and generate a gate driving signal DR based on the control signal GC. The gate driving signal DR may have stronger driving ability than the control signal GC.

A current monitor circuit 203 may be configured to sense the current Io flowing from the IN pin to the OUT pin. The current monitor circuit 203 may be configured to generate a corresponding sensed current signal ICS that is indicative of the current flowing from the IN pin to the OUT pin. In an embodiment, the sensed current signal ICS may be in the form of a current signal. The current monitor circuit 203 may apply or use or involve a current sensing coefficient KCS between the current Io flowing from the IN pin to the OUT pin and the sensed current signal ICS, that is, KCS=ICS/Io. In an embodiment, the IC 110 may convert the sensed current signal ICS to the current sense signal VCS at the CS pin with a current to voltage conversion gain RCS applied between the sensed current signal ICS and the current sense signal VCS, that is, VCS=ICS*RCS=KCS*RCS*Io. For this situation, the predetermined current sense gain GCS between the current sense signal VCS and the current Io flowing from the IN pin to the OUT pin may be determined by the current sensing coefficient KCS between the current Io flowing from the IN pin to the OUT pin and the sensed current signal ICS, and the current to voltage conversion gain RCS between the current sense signal VCS and the sensed current signal ICS, that is, GCS=KCS*RCS. Both of the current sensing coefficient KCS and the current to voltage conversion gain RCS may be set or chosen according to design or application specifications. The current monitor circuit 202 may be coupled to the CS pin and the current sense signal VCS may be provided at the CS pin. In an embodiment, for instance, the current sense signal VCS may be generated at the CS pin when a resistive element R7 (see FIG. 1) having a resistance RCS coupled to the CS pin, i.e., coupled between the CS pin and the ground GND. The resistance RCS of the resistive element R7 determines the current to voltage conversion gain RCS in this example. One of ordinary skill in the art would understand that specific implementation configurations are just provided here as examples and not intended to be limiting. Any other suitable current sensing techniques and circuits are applicable to provide the current sense signal VCS at the CS pin and do not depart from the spirit and scope of the present invention. In an embodiment, the current sense signal VCS at the CS pin may be clamped at the predetermined clamp voltage threshold VCS_CL (for instance set to be 3V in an example) once the current sense signal VCS reaches the predetermined clamp voltage threshold VCS_CL.

In an embodiment, as shown in the example of FIG. 2, the IC 110 may further include a fault diagnostic circuit 204 coupled to the FLT pin. The current monitor circuit 203 may be coupled to the fault diagnostic circuit 204 to provide an over current indication signal SCP to the fault diagnostic circuit 204. In an embodiment, the current monitor circuit 203 may be configured to monitor or identify whether a fault event such as an over current event or a short circuit event is occurring based on the sensed current signal ICS and may provide the over current indication signal SCP to the fault diagnostic circuit 204. In this example, when the sensed current signal ICS indicates that the output current Io or the load current reaches or exceeds an over current threshold loc (e.g., 200A), the current monitor circuit 203 may determine that the over current event or the short circuit event is occurring, or alternatively speaking, the over current event or the short circuit event is identified or detected. In an alternative embodiment, the current monitor circuit 203 may provide the sensed current signal ICS (instead of the over current indication signal SCP) to the fault diagnostic circuit 204 and the fault diagnostic circuit 204 may be configured to monitor or identify whether a fault event such as the over current event or the short circuit event is occurring based on the sensed current signal ICS. In this example, when the sensed current signal ICS indicates that the output current Io or the load current reaches or exceeds the over current threshold loc (e.g., 200A), the fault diagnostic circuit 204 may determine that the over current event or the short circuit event is occurring, or alternatively speaking, the over current event or the short circuit event is identified or detected. Once the over current event or the short circuit event is identified or detected, the IC 110 may be shut down immediately to protect the power switch 201 and the IC 110 from being damaged due to large crush current. For instance, the fault diagnostic circuit 204 may be configured to provide a fault protection signal PRO to the control module 202. Once the over current event or the short circuit event is identified or detected, the fault diagnostic circuit 204 may be configured to trigger, for instance by the fault protection signal PRO, the control module 202 to turn off the power switch 201, meanwhile the fault diagnostic circuit 204 may pull the fault indication pin FLT to a logic low to indicate that a fault event is identified or detected.

In an embodiment, as shown in the example of FIG. 2, the IC 110 may further include a fuse-like protection circuit 205. The fuse-like protection circuit 205 may be coupled to the current monitor circuit 203 to receive the sensed current signal ICS. The fuse-like protection circuit 205 may further be coupled to the fuse-like protection pin FUSE. The fuse-like protection circuit 205 may be configured to implement the fuse-like current limit protection when a capacitive element such as a capacitor C1 as exemplarily shown in FIG. 1 is coupled between the fuse-like protection pin FUSE and the ground pin GND. The fuse-like protection circuit 205 may have a current threshold indicative of the fuse current limit threshold IFUSE_CL and may provide the fuse current Ifuse to charge the capacitive element C1 when the output current Io exceeds the fuse current limit threshold IFUSE_CL (for instance when the sensed current signal exceeds the current threshold indicative of the fuse current limit threshold IFUSE_CL) or when the current sense signal VCS at the CS pin reaches the predetermined clamp voltage threshold VCS_CL. The fuse-like protection circuit 205 may further be configured to trigger shut down of the IC 110 after a fuse-like protection period (or time interval) Tfuse since the moment when the IC 110 enters the fuse-like protection mode (i.e., since the moment when the output current Io exceeds the fuse current limit threshold IFUSE_CL or since the moment when the current sense signal VCS at the CS pin reaches the predetermined clamp voltage threshold VCS_CL). In an embodiment, the fuse-like protection circuit 205 may be configured to start discharging the capacitive element C1 each time when the fuse voltage Vfuse at the FUSE pin reaches a fuse-like protection mode clamp voltage threshold Vfuse_CL (e.g., at time t2 in FIG. 6), and to stop discharging the capacitive element C1 and to make a fuse-like protection record each time when the fuse voltage Vfuse drops essentially to a discharge stop threshold Vfuse_low. The fuse-like protection circuit 205 may be further configured to immediately trigger the IC 110 to be shut down (for instance by providing a fuse-like protection signal Pfuse to the fault diagnostic circuit 204 to let the fault protection signal PRO to trigger the control module 202 to turn off the power switch 201) and to let the fault diagnostic circuit 204 to pull the fault indication pin FLT to a logic low when the record number Nfuse indicative of the times that the fuse-like protection record has been made reaches a predetermined number M. In an embodiment, if the output current Io decreases for instance below the fuse current limit threshold IFUSE_CL or the current sense signal VCS drops below the clamp voltage threshold VCS_CL before the record number Nfuse reaches the predetermined number M, the fuse-like protection circuit 205 may further be configured to decrease the record number Nfuse by minus 1 each time when the fuse voltage Vfuse is charged to the fuse-like protection mode clamp voltage threshold Vfuse_CL and then subsequently discharged to the discharge stop threshold Vfuse_low.

In certain circumstances, from IC level, there could be random hardware failure which may cause the power switch short to ground (short circuit) or there could be large voltage spikes at the input pin IN which may exceed the ABS (safe operation range) of the input voltage VIN from system level which may cause destructive large current stress. The IC 110 may fail in these circumstances or fault events and the IC level protection functions such as over current or short circuit protection (e.g., the current monitor circuit 203 and the fault diagnostic circuit 204), fuse-like current limit protection (e.g., the fuse-like protection circuit 205) etc. may not work. Therefore, in accordance with an exemplary embodiment of the present invention, the IC 110 may further have a package level fuse protection structure integrated in a package of the IC 110. For instance, the package level fuse protection structure may be integrated and couped in series with the output pin OUT in an embodiment. The package level fuse protection structure may be melt or “blown up” to form an open circuit when a current over a predetermined fuse current value (e.g., over 80 A in an example) flows through it.

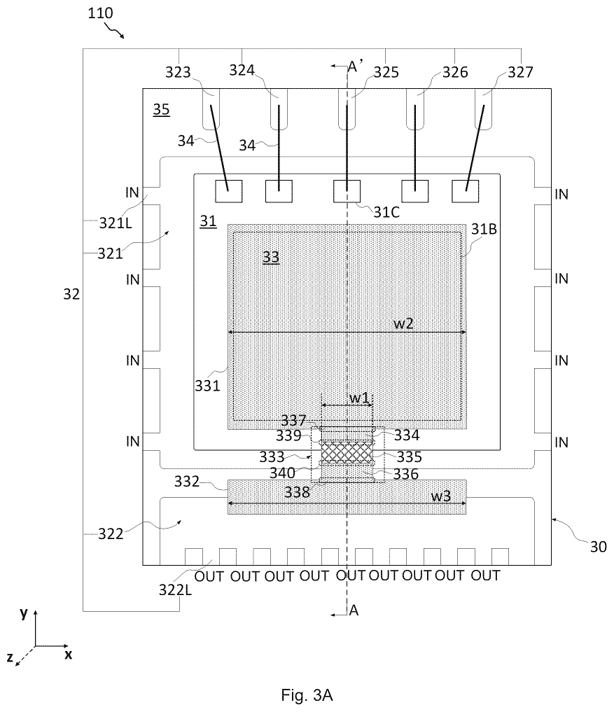

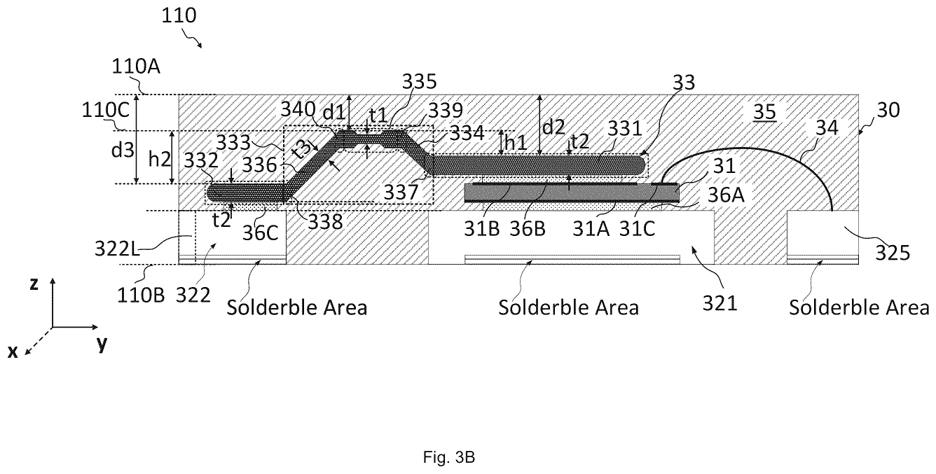

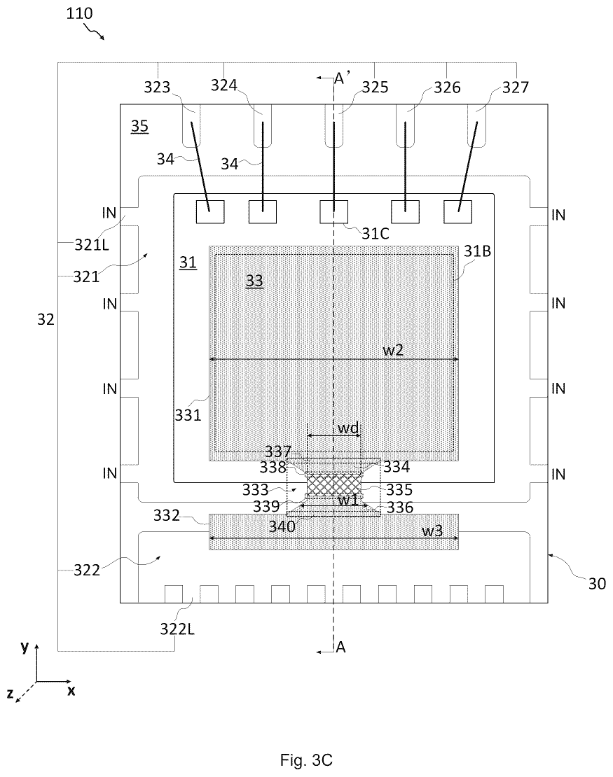

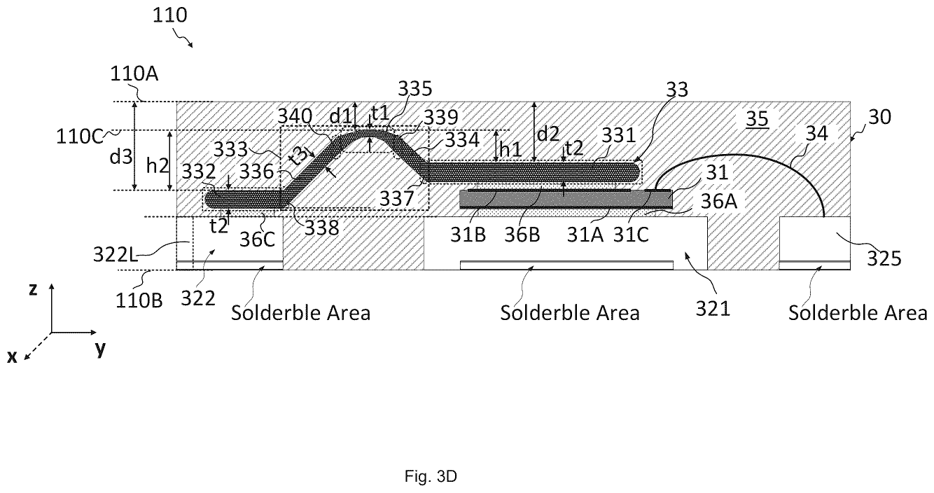

FIG. 3A illustratively shows a top plan view of the IC chip 110 in a package 30 in accordance with an embodiment of the present invention. FIG. 3B illustratively shows a cross-sectional view of the IC chip 110 taken along the sectional line A-A′ in top plan view of FIG. 3A in accordance with an embodiment of the present invention. The top plan view in FIG. 3A and the cross-sectional view in FIG. 3B may be considered as illustrated out in a 3-dimensional coordinate system having the x axis, y axis and z axis perpendicular to one another. It may be understood that the illustrative cross-sectional view may be considered as inspected from/taken from a cutting plane parallel to the y-z plane defined by the y and z axis. Throughout this disclosure, lateral may refer to a direction parallel to the y axis while vertical may refer to a direction parallel to the z axis in the cross-sectional views. Width may refer to a size measured in the direction parallel to the x axis, length may refer to a size measured in the direction parallel to the y axis and height, depth and/or thickness may refer to a size measured in the direction parallel to the z axis. The IC 110 may be packaged in a package 30 that may be described and understood with reference to FIG. 3A and FIG. 3B collectively. The IC 110 may have a top surface 110A and a bottom surface 110B opposite to the top surface 110A. One of ordinary skill in the art would understand that the top surface 110A and the bottom surface 110B may also be respectively referred to or considered as the top surface and the bottom surface of the package 30.

The IC 110 may include an IC bare die 31 disposed and mounted on a lead frame 32 of the package 30. The IC bare die 31 may have a die top surface and a die bottom surface opposite to the die top surface. The IC bare die 31 may have integrated circuit elements such as the power switch 201 fabricated therein. There may be one or more contact pads formed on the die top surface and/or the die bottom surface to electrically lead terminals of the integrated circuit elements out. In an embodiment, the integrated circuit elements fabricated in the IC bare die 31 may include other circuitries such as those for controlling the power switch 201, in addition to the power switch 201. For instance, those circuitries for controlling the power switch 201 may include but not limited to the control module 202, the current monitor circuit 203, the fault diagnostic circuit 204, the fuse-like protection circuit 205 etc. as exemplarily shown and depicted with reference to FIG. 2, and may be collectively referred to as control circuitry herein after. In an alternative embodiment, while the power switch 201 is fabricated in the IC bare die 31, the control circuitry may be fabricated on a separate controller bare die which may be co-packaged with the IC bare die 31 in the package 30, which should be well known and just a matter of choice to one of ordinary skill in the art, and do not need to be addressed in detail here to avoid obscuring aspects of the present invention and do not depart from the spirit and scope of the present invention.

In an example, as will be described with reference to FIG. 3A and FIG. 3B, the power switch 201 fabricated in the IC bare die 31 may include a vertical transistor device. In an embodiment, a first contact pad 31B and a third contact pad 31C may be formed at the die top surface of the IC bare die while a second contact pad 31A may be formed at the die bottom surface of the IC bare die 31. It would be obvious to those skilled in the art that there may be more or less contact pads formed at either the die bottom surface or the die top surface according to practical application or design requirements. In an embodiment, for a vertical transistor device fabricated in the IC bare die 31, the second contact pad 31A formed at the die bottom surface may provide electrical contact for a second terminal (e.g., drain) of the vertical transistor device to be connected and led out. The first contact pad 31B and the third contact pad 31C formed at the die top surface may respectively provide electrical contacts for a first terminal (e.g., source) and a control terminal (e.g., gate) of the vertical transistor device to be connected and led out. In the example where the power switch 201 and its control circuitry are integrated in a single IC bare die 31, the third contact pad 31C may instead provide electrical contact for a control terminal (e.g., an enable terminal to be connected to the EN pin) of the IC chip 110.

The lead frame 32 may be formed of electrically conductive materials such as metal, metal composition or alloy etc. For instance, in an embodiment, the lead frame 32 may be of copper, aluminum, nickel etc., or alloys thereof. The lead frame 32 may be adapted to provide physical support to bare die(s) such as the IC bare die 31 and/or the controller bare die being packaged in the package 30. The lead frame 32 may further be adapted to provide electrical coupling and/or electrical connection so that electrical coupling and/or electrical connection and/or signal communication between the bare die(s) inside the package 30 and/or between the bare die(s) and other external circuits or elements outside the IC chip 110 may be realized.

In accordance with an embodiment, the lead frame 32 may include a first portion 321 placed at a middle area of the package 30, a second portion 322 placed at a first peripheral area (e.g., at the lower side in the exemplary top plan view of FIG. 3A) of the package 30, and a plurality of third portions 323˜327 placed at a second peripheral area (e.g., at the upper side in the exemplary top plan view of FIG. 3A) of the package 30. One of ordinary skill in the art would understand that locations of the first portion 321, the second portion 322 and the plurality of third portions 323˜327 here are just for exemplary and illustrative purposes and not intended to be limiting, which may be adjusted or changed according to practical application and design specifications in other embodiments. The first portion 321, the second portion 322 and the plurality of third portions 323˜327 may be separated from each other, for instance, by an encapsulation material 35. The encapsulation material 35 may include various package filler materials that may be electrically isolative, thermally conductive and flame retardants etc. For instance, in an embodiment, the encapsulation material 35 may include epoxy material etc. The encapsulation material 35 may be formed such that the IC bare die 31 and other bare dies that may be co-packaged with the IC bare die 31 are encapsulated, and such that each of the first portion 321, the second portion 322 and the plurality of third portions 323˜327 may at least have a portion or a surface that is at least partially exposed from the encapsulation material 35 to outside of the package 30. For instance, in the example of FIG. 3B, a bottom surface of the first portion 321, a bottom surface of the second portion 322 and bottom surfaces of outer ends of the third portions 323˜327 are exposed from the encapsulation material 35.

The first portion 321 of the lead frame 32 may be adapted to receive the IC bare die 31. In an embodiment, the IC bare die 31 may be mounted on the first portion 321 with the die bottom surface of the IC bare die 31 (including the second contact pad 31A) attached to the first portion 321 by an electrically conductive die attaching material (e.g., solder paste) 36A for example. The first portion 321 may have a plurality of leads 321L extending from the first portion 321 outwardly to at least a third peripheral area of the package 30 so that the leads 321L may be used for providing electrical or signal communication with other elements outside the IC chip 110. In the example of FIG. 3A, the plurality of leads 321L are illustratively shown to extend to a third peripheral area (e.g., at the left side in the exemplary top plan view of FIG. 3A) and a fourth peripheral area (e.g. at the right side in the exemplary top plan view of FIG. 3A) of the package 30. The plurality of leads 321L may be adapted to function as a plurality of input leads of the input pin IN of the IC chip 110 in the example shown in FIG. 3A. In this fashion, the second terminal (e.g., drain) of the power switch 201 which may include the vertical transistor device in this example may be electrically coupled to the input pin IN of the IC chip 110.

The second portion 322 of the lead frame 32 may have a plurality of leads 322L extending from the second portion 322 outwardly so that the leads 322L may be used for providing electrical or signal communication between the IC chip 110 and other elements outside the IC chip 110. In the example of FIG. 3A, the plurality of leads 322L may be adapted to function as a plurality of output leads of the output pin OUT of the IC chip 110. In an embodiment, the second portion 322 may be adapted to be configured as or to function as an electrically conductive lead pad that may be adapted to be electrically coupled to the IC bare die for example to the first contact pad 31B at the die top surface of the IC bare die 31 and to provide electrically conductive lead out for the IC bare die 31 so that the IC bare die 31 can have electrical coupling or signal communication with outside of the package 30.

The plurality of third portions 323˜327 may be adapted to respectively function as other pins such as the EN pin, the FLT pin, the GND pin, the CS pin, the FUSE pin and the TS pin etc. of the IC 110 that have been described with reference to the examples shown in FIG. 1 and FIG. 2. The plurality of third portions 323˜327 may therefore be respectively connected to corresponding contact pads of the bare die(s) such as the IC bare die 31 and/or the controller bare die being packaged in the package 30 through bond wires 34. One of ordinary skill in the art would understand that this is not intended to be limiting and the IC 110 may include different pins more or less than those described herein according to practical application requirements or design specifications.

In an embodiment, an electrically conductive connector 33 may be coupled or connected between the first contact pad 31B of the IC bare die 31 and the second portion 322 of the lead frame 32. In this fashion, the first terminal (e.g., source) of the power switch 201, which may include the vertical transistor device in this example, may be electrically coupled to the output pin OUT of the IC chip 110.

In an embodiment, the electrically conductive connector 33 may include a connector bridging portion 333 having a reduced size in comparison with a remainder of the electrically conductive connector 33. The remainder of the electrically conductive connector 33 here is mentioned relative to the connector bridging portion 333 of the electrically conductive connector 33 and mean portion(s) of the electrically conductive connector 33 except the connector bridging portion 333. In the examples illustratively shown in FIG. 3A and FIG. 3B, the remainder of the electrically conductive connector 33 may include a first connector spreader portion 331 adapted to be coupled to the IC bare die 31 and a second spreader portion 332 adapted to be coupled to the second portion 322 of the lead frame 32, the connector bridging portion 333 may be between the first connector spreader portion 331 and the second connector spreader portion 332. It should be understood by persons of ordinary skill in the art that the examples here are provided just for helping to understand embodiments of the present invention and not intended to be limiting. In other embodiments, the remainder of the electrically conductive connector 33 may include more or less portions.

The connector bridging portion 333 with reduced size may advantageously form a fuse structure integrated in the package 30. In a fault event causing large current over a predetermined fuse current value (e.g., over 80 A in an example) that would flow through the electrically conductive connector 33, the fuse structure 333 melts to cut off or open an electrically conductive path provided by the electrically conductive connector 33 between the first contact pad 31B of the IC bare die 31 and the second portion 322 of the lead frame 32, and thus prevents catastrophic destruction to the IC chip 110 and/or a circuit board the IC chip 110 is mounted on and/or other elements mounted on the circuit board to co-work with the IC chip 110 for instance.

In an embodiment, as exemplarily shown in FIG. 3A, the connector bridging portion 333 of the electrically conductive connector 33 may have a reduced size in comparison with the remainder of the electrically conductive connector 33 in the top plan view (e.g., x-y) dimension. The connector bridging portion 333 may look like a neck compared to the remainder of the electrically conductive connector 33. For instance, the connector bridging portion 333 may have a smaller or narrower width w1 than the remainder of the electrically conductive connector 33. The narrower neck-like connector bridging portion 333 may advantageously form the fuse structure integrated in the package 30 in this example.

In an embodiment, as exemplarily shown in FIG. 3B, the connector bridging portion 333 (or alternatively speaking the fuse structure 333) of the electrically conductive connector 33 may have a reduced size in comparison with the remainder of the electrically conductive connector 33 in the cross-sectional view (e.g., x-z or y-z) dimension perpendicular to the top plan view (i.e., x-y) dimension. That is, the connector bridging portion 333 may have a portion having a smaller cross-sectional area. The connector bridging portion 333 with smaller cross-sectional area in comparison with the remainder of the electrically conductive connector 33 may advantageously form the fuse structure integrated in the package 30 in this example. For example, in an embodiment, at least a portion of the connector bridging portion 333 may have a reduced size in the z axis dimension. In an embodiment, the connector bridging portion 333 may be formed to at least have a portion with a smaller first thickness t1 in comparison with the remainder of the electrically conductive connector 33. In an embodiment, the remainder of the electrically conductive connector 33 may have a substantially uniform second thickness t2 that is thicker than the first thickness t1 (i.e., t1<t2) so that the portion with the smaller first thickness t1 may be more easily melt or blown up.

In an embodiment, the connector bridging portion 333 may have a reduced size in comparison with the remainder of the electrically conductive connector 33 both in the top plan view (i.e., x-y) dimension and in the cross-sectional view (e.g., x-z or y-z) dimension, as may be understood with reference to the examples shown in FIG. 3A and FIG. 3B in combination.

In an embodiment, the connector bridging portion 333 may have an elevated portion (e.g., 335 in the example illustratively shown in FIG. 3B) that is protruding relative to the remainder of the electrically conductive connector 33. When the electrically conductive connector 33 is used in a package (such as the package 30) for an integrated circuit (such as the IC 110), for instance being mounted in the package 30 with the elevated portion disposed near the top surface 110A of the package 30 (or the IC chip 110), the elevated portion is vertically higher than the remainder of the electrically conductive connector 33 with reference to the bottom surface 110B of the package 30 (or the IC chip 110). Alternatively speaking, the elevated portion of the connector bridging portion 333 (or the fuse structure 333) may advantageously at least have a section having a reduced buried depth d1 (e.g., in the encapsulation material 35) with reference to the top surface 110A of the IC chip 110 than the remainder of the electrically conductive connector 33 when mounted in the package 30 with the elevated portion disposed near the top surface 110A of the package 30 (or the IC chip 110). In the example shown in FIG. 3B, the elevated portion 335 is illustrated to be elevated to at least have a section having the buried depth d1 that is smaller or shallower than a buried depth d2 of the first connector spreader portion 331 and a buried depth d3 of the second connector spreader portion 332 with reference to the top surface 110A of the IC chip 110. The connector bridging portion 333 (or the fuse structure 333) having the elevated portion which at least includes a section having a reduced buried depth d1 (e.g., in the encapsulation material 35) with reference to the top surface 110A may be beneficial to eliminating or at least reducing the risk of causing flame and/or forming a secondary conductive path during the process when the fuse structure 333 melts.

In an embodiment, the connector bridging portion 333 may be formed like a bridge built over a space or a gap between the first portion 321 and the second portion 322 of the lead frame 32 so that the electrically conductive connector 33 in its entirety may function as the electrically conductive path that may be adapted to electrically connect the first contact pad 31B of the IC bare die 31 to the second portion 322 and the plurality of leads 322L of the lead frame 32. In the following, descriptions will be made with reference to the examples illustratively shown in FIG. 3A and FIG. 3B.

In an embodiment, the electrically conductive connector 33 may include the first connector spreader portion 331 having a relatively large area that may be substantially in compatible with or match with that of the second contact pad 31B of the IC bare die 31 so that contact/connection area between the first contact pad 31B of the IC bare die 31 and the electrically conductive connector 33 may be as large as possible. The first connector spreader portion 331 may be substantially flat in the top plan view dimension as illustrated in FIG. 3A and may be disposed atop the IC bare die 31 as can be inspected from the cross-sectional view as illustrated in FIG. 3B. The first connector spreader portion 331 may be electrically coupled or connected to the first contact pad 31B on the die top surface of the IC bare die 31. For instance, in the examples of FIG. 3A and FIG. 3B, it is illustratively shown that the first connector spreader portion 331 is attached to the first contact pad 31B of the IC bare die 31 by an electrically conductive die attaching material (e.g., solder paste) 36B. The first connector spreader portion 331 with the relatively large area may enhance the contact/connection area between the first contact pad 31B of the IC bare die 31 and the electrically conductive connector 33 and thus improve the current or power transmission capability there between.

In an embodiment, the electrically conductive connector 33 may further include the second connector spreader portion 332 having an area that may be substantially in compatible with or match with the second portion 322 of the lead frame 32 so that contact/connection area between the second connector spreader portion 332 of the electrically conductive connector 33 and the second portion 322 of the lead frame 32 may be as large as possible. The second connector spreader portion 332 may be substantially flat in the top plan view dimension as illustrated in FIG. 3A and may be disposed atop the second portion 322 of the lead frame 32 as can be inspected from the cross-sectional view as illustrated in FIG. 3B. The second connector spreader portion 332 may be electrically coupled or connected to the second portion 322 of the lead frame 32. For instance, in the example of FIGS. 3A and 3B, it is illustratively shown that the second connector spreader portion 332 is attached to the second portion 322 of the lead frame 32 by an electrically conductive die attaching material (e.g., solder paste) 36C.

In an embodiment, the connector bridging portion 333 of the electrically conductive connector 33 connects the first connector spreader portion 331 and the second connector spreader portion 332 in the manner like a bridge built between the first connector spreader portion 331 and the second connector spreader portion 332. The connector bridging portion 333 is like a bridge in that it is formed over a space or a gap between the first portion 321 and the second portion 322 of the lead frame 32 so that the first connector spreader portion 331 is bridged and joint to the second connector spreader portion 332 and the electrically conductive connector 33 in its entirety may function as an electrically conductive path that may be adapted to electrically connect the first contact pad 31B of the IC bare die 31 to the second portion 322 and the plurality of leads 322L of the lead frame 32. In an embodiment, the connector bridging portion 333 may have a reduced size in comparison with the first connector spreader portion 331 and the second connector spreader portion 332 in the top plan view dimension and may look like a neck connecting the first connector spreader portion 331 with the second connector spreader portion 332. For instance, the connector bridging portion 333 may have a smaller or narrower width than the first connector spreader portion 331 and the second connector spreader portion 332. That is a width w1 of the connector bridging portion 333 is smaller or narrower than a width w2 of the first connector spreader portion 331 and a width w3 of the second connector spreader portion 332, i.e., w1<w2 and w1<w3. The narrower neck-like connector bridging portion 333 may advantageously form a fuse structure integrated in the package 30. In a fault event causing large current over a predetermined fuse current value (e.g., over 80 A in an example) that would flow through the electrically conductive connector 33, the fuse structure 333 melts to cut off or open the electrically conductive path bridged between the first connector spreader portion 331 and the second connector spreader portion 332, and thus prevents catastrophic destruction to the IC chip 110 and/or a circuit board the IC chip 110 is mounted on and/or other elements mounted on the circuit board to co-work with the IC chip 110 for instance.

In an embodiment, the connector bridging portion 333 may include a first bridge support structure 334, a second bridge support structure 336 and a bridge deck structure 335 connecting the first bridge support structure 334 with second bridge support structure 336. The first bridge support structure 334 and the second bridge support structure 336 may be formed respectively at a first side and a second side of the bridge deck structure 335, and the bridge deck structure 335 may connect the first bridge support structure 334 at the first side and may connect the second bridge support structure 336 at the second side, the second side being opposite to the first side. In the examples illustratively shown in FIG. 3A and FIG. 3B, the first side of the bridge deck structure 335 may refer to the side near the first connector spreader portion 331 and the second side of the bridge deck structure 335 may refer to the side near the second connector spreader portion 332. In an embodiment, the first bridge support structure 334 and the second bridge support structure 336 may be configured to elevate the bridge deck structure 335 so that the bridge deck structure 335 or at least a portion of the bridge deck structure 335 is vertically higher than the first connector spreader portion 331 and the second connector spreader portion 332, with reference to the bottom surface 110B of the IC chip 110. In an embodiment, a first bending portion 337 of the connector bridging portion 333 may connect and joint the first connector spreader portion 331 with the first bridge support structure 334, allowing a bended (e.g., an angular or arcing) intersection between the first connector spreader portion 331 and the first bridge support structure 334 such that a direction change from the first connector spreader portion 331 to the first bridge support structure 334 is available. A second bending portion 338 of the connector bridging portion 333 may connect and joint the second connector spreader portion 332 with the second bridge support structure 336, allowing a bended (e.g., an angular or arcing) intersection between the second connector spreader portion 332 and the second bridge support structure 336 such that a direction change from the second connector spreader portion 332 to the second bridge support structure 336 is available. A third bending portion 339 of the connector bridging portion 333 may connect and joint the first bridge support structure 334 with the bridge deck structure 335, allowing a bended (e.g., an angular or arcing) intersection between the first bridge support structure 334 and the bridge deck structure 335 such that a direction change from the first bridge support structure 334 to the bridge deck structure 335 is available. A fourth bending portion 340 of the connector bridging portion 333 may connect and joint the second bridge support structure 336 with the bridge deck structure 335, allowing a bended (e.g., an angular or arcing) intersection between the first bridge support structure 334 and the bridge deck structure 335 such that a direction change from the first bridge support structure 334 to the bridge deck structure 335 is available. One of ordinary skill in the art would understand that the bending portions 337 and 339 may alternatively considered as parts of the first bridge support structure 334 being integrally formed with the first bridge structure 334, and the bending portions 338 and 340 may alternatively considered as parts of the second bridge support structure 336 being integrally formed with the second bridge support structure 336. One of ordinary skill in the art would further understand that various portions of the electrically conductive connector 33, although described and mentioned as different portions to ease the description and to help understand various features of the electrically conductive connector 33 with the fuse structure 333 integrated therein, may be integrally formed in an embodiment such that the electrically conductive connector 33 is a continuous sheet formed of electrically conductive materials such as metal, metal composition or alloy etc. For instance, in an embodiment, the electrically conductive connector 33 may be of copper, aluminum, nickel etc., or alloys thereof.

In the example as illustratively shown in FIG. 3B, the bridge deck structure 335 or at least a portion of the bridge deck structure 335 of the fuse structure 333 may advantageously have a reduced buried depth d1 in the encapsulation material 35 with reference to the top surface 110A of the IC chip 110 than the first connector spreader portion 331 and the second connector spreader portion 332. The bridge deck structure 335 being elevated and having at least a portion with the buried depth d1 that is smaller or shallower than a buried depth d2 of the first connector spreader portion 331 and a buried depth d3 of the second connector spreader portion 332 with reference to the top surface of the IC chip 110 may be beneficial to eliminating or at least reducing the risk of causing flame and/or forming a secondary conductive path during the process when the fuse structure 333 melts.

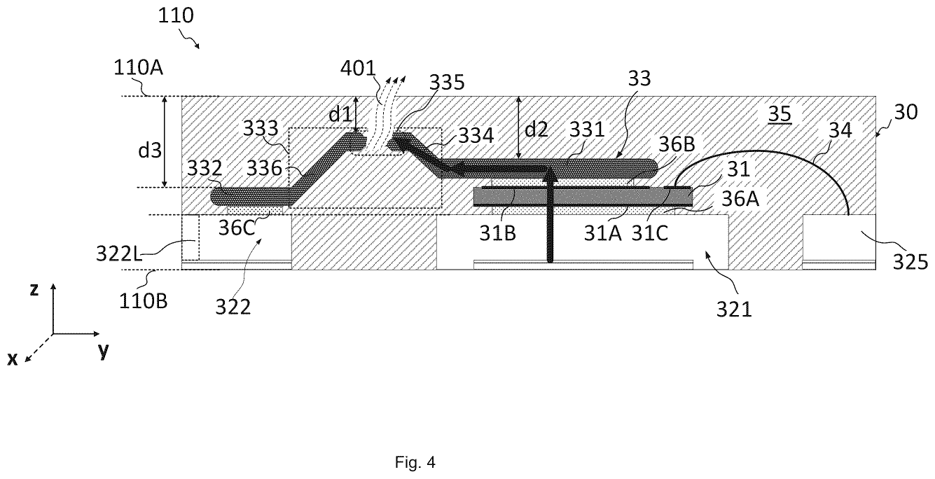

FIG. 4 illustratively shows a cross-sectional view of the IC chip 110 illustrating how a risk of causing flame or forming a secondary conductive path can be eliminated or reduced in an example embodiment. When an excessive electrical stress in a fault event resulting in a large current over the predetermined fuse current value (e.g., over 80 A in an example, illustratively shown with the thick arrows in FIG. 4) that would flow through the electrically conductive connector 33 due to for example random IC level hardware failure and/or system level excessive input stress etc., the fuse structure 333 with a narrower cross-sectional area in the x-z dimension yet crowded electrons to run through will heat and melt, especially, the elevated portion (e.g., the elevated bridge deck structure 335 with at least a portion having the smaller buried depth d1) will firstly melt and blow up to create an open circuit, and an arc will instantly form and grow with the fuse structure 333 being vaporized, resulting in a very high pressure rapidly accumulated which immediately punches or tears a hole or a slot or an opening 401 through a portion of the encapsulation material 35 that is right over the elevated portion of the fuse structure 333, all the way through to the top surface 110A of the IC chip 110 or the package 30. With a portion of the encapsulation material 35 right over the elevated portion of the fuse structure 333 being teared open, super-heated vapor of the melt fuse structure 333 can be expelled out via the hole or the slot or the opening 401, releasing the pressure around the fuse structure 333, leading to extinguish of the arc and few vaporized material of the melt fuse structure 333 left inside the package 30, preventing a secondary conductive path being formed and preventing the IC chip 110 from being burnt up.

Therefore, the connector bridging portion 333 having the elevated portion (e.g., the bridge deck structure 335 elevated with at least a portion of the bridge deck structure 335 to have the smaller or shallower buried depth d1) can form the fuse structure integrated in the package 30 that is helpful to prevent the IC chip 110 or a circuit board the IC chip 110 is mounted on and/or other elements mounted on the circuit board from being dramatically damaged (for instance burnt up) or at least to reduce the possibility of such kind of damages. A system such as the system 100 configured or mounted on a circuit board with the IC 110 mounted on the same circuit board together with other components co-working with the IC 110 may only need to replace the IC chip 110 packaged in the package 30 in case that an over stress strikes through the IC chip 100 (e.g., the power transistor 201 therein) and results in the fuse structure 333 being melt or “blown up” due to a fault event such as random IC level hardware failure and/or system level excessive input stress etc. An IC chip such as the IC 110 with the fuse structure 333 integrated in a package such as the package 30 in accordance with various embodiments of the present invention may be size saving and cost effective since it does not need additional components such as a non-conductive glass vial or a non-conductive ceramic container packed with quartz or a cavity to hold the fuse structure inside and to space the fuse structure from the encapsulation material 35 and does not need to involve in additional special manufacturing processes to fabricate.

In an embodiment, referring back to the examples shown in FIG. 3A and FIG. 3B, the elevated portion (e.g., the bridge deck structure 335) of the connector bridging portion 333 may be elevated to at least have a section of the elevated portion to reach a plane 110C which is parallel to the x-y plane and essentially has a first predetermined height h1 with reference to the top surface of the first connector spreader portion 331 and a second predetermined height h2 with reference to the top surface of the second connector spreader portion 332. In other words, the first predetermined height h1 may refer to a vertical direct distance inspected substantially from the top surface of the first connector spreader portion 331 to the plane 110C or alternatively speaking to a top surface of the section of the elevated portion (e.g., the bridge deck structure 335) which reaches the plane 110C. The second predetermined height h2 may refer to a vertical direct distance inspected substantially from the top surface of the second connector spreader portion 331 to the plane 110C or alternatively speaking to the top surface of the section of the elevated portion (e.g., the bridge deck structure 335) which reaches the plane 110C. The buried depth d1 may be flexibly controlled and adjusted by appropriately choosing or setting the predetermined height h1 and/or the predetermined height h2 in accordance with practical application requirements. In an embodiment, the buried depth d1 may be controlled to be smaller than 150 μm. In an embodiment, the buried depth d1 may be controlled to be in a range from 30 μm to 150 μm. Being able to flexibly control and adjust the buried depth d1 could be important for various embodiments of the present invention since the buried depth d1 may affect the performance of the fuse structure 333 and the feasibility, reliability and yield of mass production of the package 30. In an embodiment, theoretically, the buried depth d1 may be substantially zero which may imply that at least a section of the elevated portion (e.g., the bridge deck structure 335) may be exposed at the top surface 110A of the IC chip 110 from the encapsulation material 35.

In an embodiment, as exemplarily shown in FIG. 3B, at least a portion of the elevated portion (e.g., the bridge deck structure 335) of the connector bridging portion 333 (or alternatively speaking the fuse structure 333) may have a reduced size in the cross-sectional view (e.g., x-z or y-z) dimension. That is, the elevated portion (e.g., the bridge deck structure 335) may have a portion having a smaller cross-sectional area. For example, in an embodiment, at least a portion of the connector bridging portion 333 may have a reduced size in the z axis dimension. In an embodiment, the elevated portion (e.g., the bridge deck structure 335) of the connector bridging portion 333 may be formed to at least have a portion with a smaller first thickness t1 in comparison with a remainder (i.e., other portions of the connector bridging portion 333 except the portion having the smaller first thickness t1) of the connector bridging portion 333. In an embodiment, the remainder of the connector bridging portion 333 may have a substantially uniform third thickness t3 that may be thicker than the first thickness t1 (i.e., t1<t3). In an embodiment, the third thickness t3 may be smaller than the second thickness t2 of the first connector spreader portion 331 and the second connector spreader portion 332. The portion with the smaller first thickness t1 of elevated portion (e.g., the bridge deck structure 335) may be more easily melt or blown up, thereby providing more timely response and protection in a fault event resulting in a large current over the predetermined fuse current value (e.g., over 80 A in an example) flowing through the electrically conductive connector 33 due to for example random IC level hardware failure and/or system level excessive input stress etc.

While specific embodiments of the present invention have been provided, it is to be understood that these embodiments are for illustration purposes only and not limiting. Many additional embodiments will be apparent to persons of ordinary skill in the art reading this disclosure.

For instance, although the connector bridging portion 333 of the electrically conductive connector 33 is illustrated to have a substantially uniform width w1 in the example of FIG. 3A, the connector bridging portion 333 may not have substantially uniform width in other embodiments as long as the connector bridging portion 333 at least has a section having a reduced width that is smaller than the width of the remainder of the electrically conductive connector 33 (e.g., smaller than the width w2 of the first connector spreader portion 331 and the width w3 of the second connector spreader portion 332). To provide an example, FIG. 3C exemplarily illustrates a top plan view of the IC chip 110 in accordance with an alternative embodiment of the present invention. In the example of FIG. 3C, the width w1 of the connector bridging portion 333 may gradually reduce or decrease from both the first bridge support structure 334 and the second bridge support structure 336 towards the bridge deck structure for instance, until the bridge deck structure 335 has a substantially predetermined width wd.

For another instance, in the example of FIG. 3B, although the connector bridging portion 333 of the electrically conductive connector 33 is illustrated to have a non-standard trapezoid bridge shape when inspected from the cross-sectional view (y-z plane view), it may be formed to have other shapes when inspected from the cross-sectional view (y-z plane view), such as an arch bridge shape, or other multi-bending bridge shapes as long as the connector bridging portion 333 at least has a section that is elevated with reference to both the top surface of the first connector spreader portion 331 and the top surface of the second connector spreader portion 332, just like the bridge deck structure 335 as described with reference to FIG. 3B above. To provide an example, FIG. 3D exemplarily illustrates a cross-sectional view of the IC chip 110 taken along the sectional line A-A′ in top plan view of FIG. 3A or FIG. 3C in accordance with an alternative embodiment of the present invention. In the example of FIG. 3D, the connector bridging portion 333 of the electrically conductive connector 33 is illustrated to have an arch bridge shape.

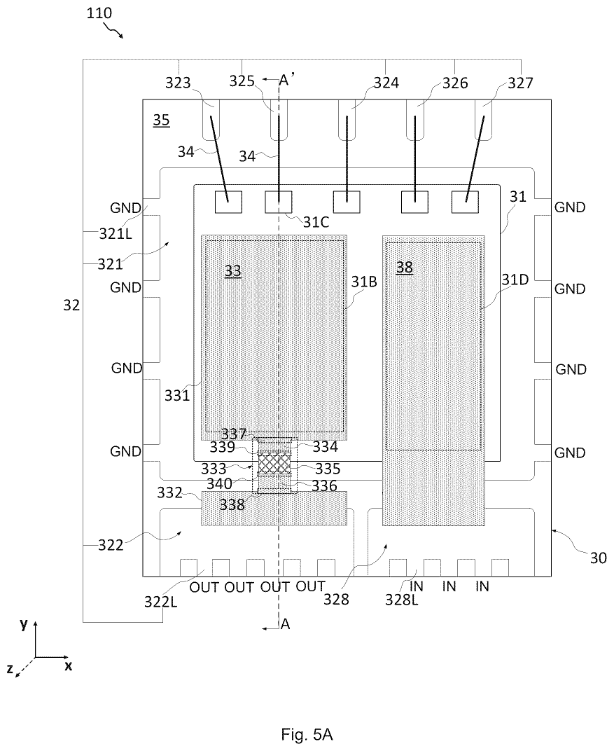

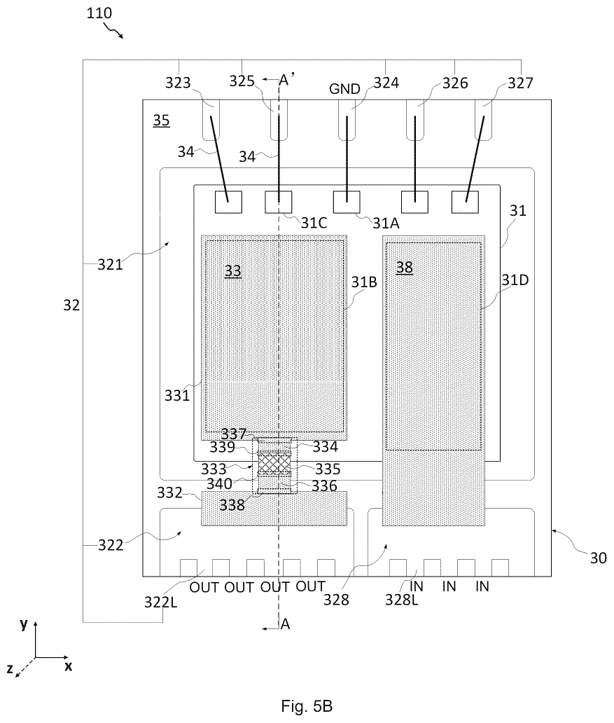

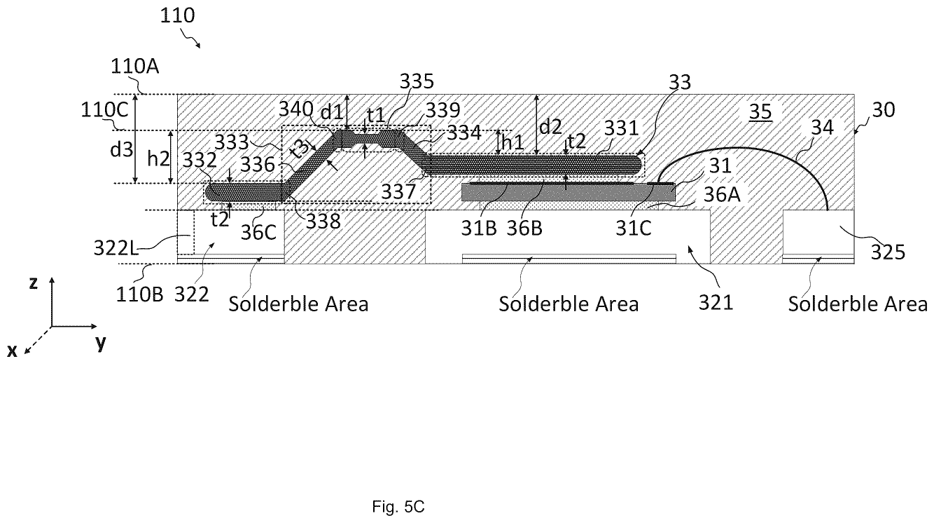

For another instance, although various embodiments described with reference to FIG. 3A to FIG. 3D take the power switch 201 including a vertical transistor device as an example, the power switch 201 fabricated in the IC bare die 31 may include a lateral transistor device in alternative embodiments. FIG. 5A illustratively shows a top plan view of the IC chip 110 in a package 30 in accordance with still an alternative embodiment of the present invention. Those skilled in the art should understand that most of the above descriptions to the IC 110 packaged in the package 30 with reference to FIG. 3A to FIG. 3D are applicable to the example of FIG. 5A. Difference in one aspect may lie in that, in the example of FIG. 5A, the power switch 201 fabricated in the IC bare die 31 may include a lateral transistor device instead of the vertical transistor device. In the example of FIG. 5A, while the first contact pad 31B and the third contact pad 31C formed at the die top surface may still be configured to respectively provide electrical contacts for a first terminal (e.g., source) and a control terminal (e.g., gate) of the lateral transistor device to be connected and led out, a fourth contact pad 31D may further be formed at the die top surface of the IC bare die 31 for providing electrical contact for a second terminal (e.g., drain) of the lateral transistor device to be connected and led out, the second contact pad 31A formed at the die bottom surface of the IC bare die 31 may instead provide electrical contact for a third terminal (e.g., substrate) of the lateral transistor device to be connected and led out. For this situation, the IC bare die 31 may be mounted on the first portion 321 of the lead frame 32 with the die bottom surface of the IC bare die 31 attached to the first portion 321 by the electrically conductive die attaching material (e.g., solder paste) 36A for example. The plurality of leads 322L extended from the second portion 322 of the lead frame 32 may still be adapted to function as a plurality of output leads of the output pin OUT of the IC chip 110, while the plurality of leads 321L extended from the first portion 321 of the lead frame 32 may be adapted to function as a plurality of ground leads of the ground pin GND of the IC chip 110 in the example shown in FIG. 5A. In this fashion, the first terminal (e.g., source) and the third terminal (e.g., substrate) of the power switch 201 which may include the lateral transistor device in this example may be respectively electrically coupled to the output pin OUT and the ground pin GND of the IC chip 110.

In the example of FIG. 5A, the lead frame 32 may further include a fourth portion 328 that is separated from the first portion 321, the second portion 322 and the plurality of third portions 323. The fourth portion 328 may be placed at a fifth peripheral area of the package 30. In the example shown in FIG. 5A, the fourth portion 328 is exemplarily illustrated to be placed at a fifth peripheral area located at the same peripheral side of the package 30 as the first peripheral area where the first portion 321 is placed at. This is just to provide an example and not intended to be limiting, in other embodiments, the fourth portion 328 may be placed at other locations of the package 30. The fourth portion 328 of the lead frame 32 may have a plurality of leads 328L extending from the fourth portion 328 outwardly so that the leads 328L may be used for providing electrical or signal communication between the IC chip 110 and other elements outside the IC chip 110. In the example of FIG. 5A, the plurality of leads 328L may be adapted to function as a plurality of input leads of the input pin IN of the IC chip 110. A second electrically conductive connector 38 may be coupled between the fourth contact pad 31D of the second terminal (e.g., drain) of the lateral transistor device and the fourth portion 328 of the lead frame 32 for instance. Alternatively, other interconnection structures such as conductive clip or bond wires etc. may be used to couple the fourth contact pad 31D of the IC bare die 31 to the fourth portion 328 of the lead frame 32. An electrically conductive connector (such as 33 or 38) may be different from a bond wire in that it has larger area in the top plan view (i.e., x-y) dimension. In an embodiment, the second electrically conductive connector 38 may include a metal sheet or a metal clip for instance. In this fashion, the second terminal (e.g., drain) of the power switch 201 which may include the lateral transistor device in this example may be electrically coupled to the input pin IN of the IC chip 110.

Those of ordinary skill in the art can understand that a cross sectional view of the IC chip 110 taken along the sectional line A-A′ in top plan view of the example in FIG. 5A may still be considered as corresponding to the illustration in FIG. 3B or FIG. 3D and related cross-sectional view descriptions including those to the electrically conductive connector 33 having the fuse structure 333 integrated there in are still applicable here and will not be repeated again.

FIG. 5B illustratively shows a top plan view of the IC chip 110 in a package 30 in accordance with yet another alternative embodiment of the present invention. Similar as the embodiment shown in FIG. 5A, in the example of FIG. 5B, the power switch 201 fabricated in the IC bare die 31 may include a lateral transistor device. Difference of the example in FIG. 5B from the example in FIG. 5A may lie in that while a substrate of the lateral transistor device may be exposed at the die bottom surface of the IC bare die 31, the second contact pad 31A for providing electrical contact for the fourth terminal (e.g., substrate) of the lateral transistor device may be formed at the die top surface instead of on the die bottom surface. In the example of FIG. 5B, the second contact pad 31A may be connected to one (e.g., the one labeled with 324 as exemplarily shown in FIG. 5B) of the plurality of third portions 323˜327 of the lead frame 32 via a bond wire 34. And the third portion 324 which is connected to the second contact pad 31A may function as a ground pin GND of the IC chip 110 in this example. For this situation, the IC bare die 31 may still be mounted on the first portion 321 of the lead frame 32 with the die bottom surface of the IC bare die 31 attached to the first portion 321 by a die attaching material 36A for example. Unless there would be other contact pad(s) formed at the die bottom surface of the IC bare die 31 that may need to be led out through the first portion 321 of the lead frame 32, the plurality of leads 321L may not need to be formed and extended outwardly from the first portion 321 and the die attaching material 36A may not necessarily need to be electrically conductive in the example shown in FIG. 5B.

FIG. 5C exemplarily illustrates a cross-sectional view of the IC chip 110 taken along the sectional line A-A′ in top plan view of FIG. 5B in accordance with yet another alternative embodiment of the present invention. Those of ordinary skill in the art can understand that except the contact pad 31A being no longer formed at the die bottom surface in FIG. 5C, descriptions made with reference to the cross-sectional views as illustrated in the examples of FIG. 3B or FIG. 3D including those to the electrically conductive connector 33 having the fuse structure 333 integrated there in are still applicable here for the example of FIG. 5C and will not be repeated again.

Those skilled in the art should understand that the above descriptions to the IC chip 110 and related package 30 having the fuse structure 333 of the various embodiments of the present disclosure made with reference to FIG. 1 to FIG. 6 are just to provide examples. The fuse structure 333 integrated in an electrically conductive connector such as the electrically conductive connector 33 as described may be applicable to other IC chips or packages for providing a package level fuse protection.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments.

What is claimed is:

1. An integrated circuit (“IC”) chip, comprising:
a lead frame including a first portion and a second portion separated from each other;
an IC bare die mounted on the first portion of the lead frame with a die bottom surface of the IC bare die attached to the first portion and a die top surface of the IC bare die having a first contact pad formed, the die top surface being opposite to the die bottom surface; and
an electrically conductive connector coupled between the first contact pad and the second portion of the lead frame, wherein the electrically conductive connector includes a connector bridging portion having a reduced size in comparison with a remainder of the electrically conductive connector; and
wherein the connector bridging portion has an elevated portion being vertically higher than the remainder of the electrically conductive connector with reference to a bottom surface of the IC chip.

2. The IC chip of claim 1, wherein the connector bridging portion has a reduced size in comparison with the remainder of the electrically conductive connector in a top plan view dimension.

3. The IC chip of claim 1, wherein the connector bridging portion has a width smaller than a width of the remainder of electrically conductive connector.

4. The IC chip of claim 1, wherein the elevated portion of the connector bridging portion at least has a section having a buried depth that is smaller or shallower than a buried depth of the remainder of electrically conductive connector with reference to a top surface of the IC chip, the top surface of the IC chip being opposite to the bottom surface of the IC chip.

5. The IC chip of claim 4, wherein the buried depth of the elevated portion is no greater than 150 μm away from the top surface of the IC chip.

6. The IC chip of claim 1, wherein the remainder of the electrically conductive connector includes a first connector spreader portion adapted to be coupled to the IC bare die and a second connector spreader portion adapted to be coupled to the second portion of the lead frame, and wherein the connector bridging portion connects between the first connector spreader portion and the second connector spreader portion.

7. The IC chip of claim 6, wherein the elevated portion of the connector bridging portion at least has a section reaching a plane having a first predetermined height with reference to a top surface of the first connector spreader portion and a second predetermined height with reference to a top surface of the second connector spreader portion.

8. The IC chip of claim 1, wherein the connector bridging portion has a reduced size in comparison with the remainder of the electrically conductive connector in a cross sectional view.

9. The IC chip of claim 1, wherein the elevated portion has a portion having a reduced size in a cross sectional view dimension in comparison with a remainder of the connector bridging portion.

10. The IC chip of claim 1, wherein the connector bridging portion includes:
a first bridge support structure;
a second bridge support structure; and
a bridge deck structure connecting the first bridge support structure with the second bridge support structure, and wherein the first bridge support structure and the second bridge support structure are configured to elevate the bridge deck structure so that the bridge deck structure or at least a portion of the bridge deck structure is vertically higher than the remainder of the electrically conductive connector with reference to the bottom surface of the IC chip.

11. The IC chip of claim 10, wherein the connector bridging portion further includes:
a first bending portion connecting the first connector spreader portion with the first bridge support structure;
a second bending portion connecting the second connector spreader portion with the second bridge support structure;
a third bending portion connecting the first bridge support structure with the bridge deck structure; and
a fourth bending portion connecting the second bridge support structure with the bridge deck structure.

12. The IC chip of claim 10, wherein the connector bridging portion has a width gradually reducing from both the first bridge support structure and the second bridge support structure towards the bridge deck structure.

13. The IC chip of claim 1, wherein the connector bridging portion has a non-standard trapezoid bridge shape or an arch bridge shape or other multi-bending bridge shape when inspected from a cross-sectional view.

14. The IC chip of claim 1, wherein the lead frame further includes a plurality of third portions separated from each other and separated from the first portion and the second portion.

15. The IC chip of claim 1, wherein the second portion of the lead frame has a plurality of leads extending from the second portion outwardly.

16. The IC chip of claim 1, wherein the IC bare die further has a second contact pad formed at the die bottom surface of the IC bare die, and wherein the IC bare die includes a power switch having a first terminal and a second terminal, and wherein the first contact pad is configured to provide electrical contact for the first terminal of the power switch, and wherein the second contact pad is configured to provide electrical contact for the second terminal of the power switch, and wherein the second contact pad is electrically coupled to the first portion of the lead frame.

17. The IC chip of claim 1, wherein the lead frame further includes a fourth portion separated from the first portion and the second portion, and wherein the IC bare die further has a second contact pad formed at the die bottom surface and a third contact pad and a fourth contact pad formed at the die top surface, and wherein the second contact pad is electrically coupled to the first portion of the lead frame, and wherein the fourth contact pad is electrically coupled to the fourth portion of the lead frame.

18. The IC chip of claim 17, wherein the second contact pad is formed at the die top surface instead of on the die bottom surface, and wherein the second contact pad is coupled to one of a plurality of third portions of the lead frame by a bond wire.

19. The IC chip of claim 17, wherein the IC bare die includes a power switch having a first terminal and a second terminal, and wherein the first contact pad is configured to provide electrical contact for the first terminal of the power switch, and the fourth contact pad is configured to provide electrical contact for the second terminal of the power switch.

20. The IC chip of claim 19, wherein the power switch further has a third terminal and a control terminal, and wherein the second contact pad and the third contact pad are respectively configured to provide electrical contact for respectively the third terminal and the control terminal of the power switch.

21. The IC chip of claim 1, wherein the IC chip further includes an input pin, an output pin, and a current sense pin adapted to be configured to provide a current sense signal indicative of a current flowing between the input pin and the output pin, and wherein the current sense signal is clamped at a predetermined clamp voltage threshold once the current sense signal reaches the predetermined clamp voltage threshold.

22. The IC chip of claim 1, wherein the IC chip further includes a fuse-like protection pin adapted to be configured to support a fuse-like protection mode when a capacitive element is coupled to the fuse-like protection pin, and wherein the IC chip is configured to enter into the fuse-like protection mode once a fuse-like protection threshold is triggered.

23. The IC chip of claim 22, wherein the IC chip is further configured to shut down after a fuse-like protection period since the moment when the IC chip enters into the fuse-like protection mode.

24. The IC chip of claim 23, wherein the fuse-like protection period varies in opposite direction with a current flowing through an output pin of the IC chip.

25. The IC chip of claim 22, wherein in the fuse-like protection mode, the IC chip is further configured to charge and discharge a fuse voltage at the fuse pin between a fuse-like protection mode clamp voltage threshold and a discharge stop threshold by charging and discharging the capacitive element.

26. The IC chip of claim 25, wherein the IC chip is further configured to start discharging the capacitive element each time when the fuse voltage at the fuse-like protection pin reaches the fuse-like protection mode clamp voltage threshold, and to stop discharging the capacitive element each time when the fuse voltage is discharged essentially to the discharge stop threshold.

27. The IC chip of claim 25, wherein the IC chip is further configured to shut down once a record number indicative of the times that the fuse voltage is charged to the fuse-like protection mode clamp voltage threshold and then discharged to the discharge stop threshold reaches a predetermined number.

28. The IC chip of claim 27, wherein during a current flowing through the output pin is above a fuse current limit threshold or during a current sense signal is at a predetermined clamp voltage threshold, the IC chip is further configured to increase the record number by 1 each time the fuse voltage is charged to the fuse-like protection mode clamp voltage threshold and then discharged substantially to the discharge stop threshold, and wherein if the current flowing between the input pin and the output pin drops below the fuse current limit threshold or the current sense signal drops below the predetermined clamp voltage threshold before the record number reaches the predetermined number, the IC chip is further configured to decrease the record number by 1 each time when the fuse voltage is charged to the fuse-like protection mode clamp voltage threshold and then discharged substantially to the discharge stop threshold.

29. An electrically conductive connector adapted to be used in a package for an integrated circuit (“IC”), comprising:
a connector bridging portion having a reduced size in comparison with a remainder of the electrically conductive connector; wherein
the connector bridging portion has an elevated portion that is protruding relative to the remainder of the electrically conductive connector.

30. The electrically conductive connector of claim 29, wherein the connector bridging portion has a width smaller than a width of the remainder of electrically conductive connector.

31. The electrically conductive connector of claim 29, wherein the elevated portion is vertically higher than the remainder of the electrically conductive connector with reference to a bottom surface of the package when the electrically conductor connector is mounted in the package with the elevated portion disposed near a top surface of the package, the top surface of the package being opposite to the bottom surface of the package.

32. The electrically conductive connector of claim 29, wherein when the electrically conductor connector is mounted in the package with the elevated portion disposed near a top surface of the package, the elevated portion at least has a section having a buried depth that is smaller or shallower than a buried depth of the remainder of electrically conductive connector with reference to the top surface of the package.

33. The electrically conductive connector of claim 29, wherein the remainder of the electrically conductive connector includes a first connector spreader portion and a second connector spreader portion, and wherein the connector bridging portion connects between the first connector spreader portion and the second connector spreader portion.

34. The electrically conductive connector of claim 33, wherein the elevated portion of the connector bridging portion at least has a section reaching a plane having a first predetermined height with reference to a top surface of the first connector spreader portion and a second predetermined height with reference to a top surface of the second connector spreader portion.

35. The electrically conductive connector of claim 29, wherein the elevated portion has a portion having a reduced size in a cross sectional view dimension in comparison with a remainder of the connector bridging portion.

36. The electrically conductive connector of claim 29, wherein the connector bridging portion includes:
a first bridge support structure;
a second bridge support structure; and
a bridge deck structure connecting the first bridge support structure with the second bridge support structure, and wherein the first bridge support structure and the second bridge support structure are configured to elevate the bridge deck structure so that the bridge deck structure or at least a portion of the bridge deck structure is protruding relative to the remainder of the electrically conductive connector.

37. The electrically conductive connector of claim 36, wherein the connector bridging portion has a width gradually reducing from both the first bridge support structure and the second bridge support structure towards the bridge deck structure.

38. The electrically conductive connector of claim 29, wherein the connector bridging portion has a non-standard trapezoid bridge shape or an arch bridge shape or other multi-bending bridge shape when inspected from a cross-sectional view.

39. An integrated circuit (“IC”) chip, comprising:
an input pin adapted to be configured to receive an input power supply voltage;
an output pin adapted to be coupled to a load;
a power switch coupled between the input pin and the output pin;
a current sense pin adapted to be configured to provide a current sense signal indicative of a current flowing between the input pin and the output pin, and wherein the current sense signal is clamped at a predetermined clamp voltage threshold once the current sense signal reaches the predetermined clamp voltage threshold;
a fuse-like protection pin adapted to be configured to support a fuse-like protection mode when a capacitive element is coupled to the fuse-like protection pin, and wherein the IC chip is configured to enter into the fuse-like protection mode once a fuse-like protection threshold is triggered; and
a package level fuse protection structure integrated and couped in series with the output pin.

40. The IC chip of claim 39, wherein the fuse-like protection threshold is triggered includes when the current sense signal reaches the predetermined clamp voltage threshold or when the current flowing between the input pin and the output pin exceeds a fuse current limit threshold.
